(19) United States
(12) Patent Application Publication
(10) Pub. No.: US 2010/0237462 A1
(43) Pub. Date: Sep. 23, 2010

(54) Package Level Tuning Techniques for Propagation Channels of High-Speed Signals

(76) Inventors: Benjamin Beker, Spicewood, TX (US); James Foppiano, Austin, TX (US)

Correspondence Address: TIMOTHY M HONEYCUTT ATTORNEY AT LAW, P O BOX 1577, CYPRESS, TX, 77410, US

(21) Appl. No.: 12/406,265

(22) Filed: Mar. 18, 2009

(51) Int. Cl. H01L 27/02; H01L 21/52; H01L 21/02; H01L 23/00

(52) U.S. Cl. 257/531; 438/106; 257/E21.5; 257/E21.022; 257/E23.002; 257/E27.009

(57) ABSTRACT

Various semiconductor chip carrier substrate circuit tuning apparatus and methods are disclosed. In one aspect, a method of manufacturing is provided that includes assembling a semiconductor chip carrier substrate with a first input/output site adapted to electrically connect to an external component and a second input/output site adapted to electrically connect to an input/output site of a semiconductor chip. An inductor is placed in the semiconductor chip carrier substrate. The inductor is electrically connected between the first and second input/output sites. The inductor has a preselected inductance to reduce an impedance discontinuity between the first input/output site or the second input/output site due to coupling to a second conductor in the semiconductor chip carrier substrate.

### BACKGROUND OF THE INVENTION

1. Field of the Invention

This invention relates generally to semiconductor processing, and more particularly to apparatus and methods of reducing capacitive-based impedance discontinuity in semiconductor chip carrier substrates.

2. Description of the Related Art

Packaged integrated circuits often consist of one or more semiconductor chips mounted to a package or carrier substrate. The carrier substrate includes plural input/outputs designed to interface with input/outputs of a printed circuit board (PCB) of one sort or another. The input/outputs convey power, ground and signals. A typical conventional carrier substrate includes several conductor layers or planes stacked and interwoven with insulating material. Some of these planes are devoted to power and others to ground. Still other conductor pathways in the carrier substrate are slated for signals.

A typical signal propagation channel consists of a PCB, a PCB socket, and a carrier substrate. The conductor planes carrying ground or power in the carrier substrate tend to be large in order to efficiently convey current. However, the current carrying efficiency comes with a penalty in the form of significant electrical parasitics which hamper the quality of signals propagating on the signals channels associated with the carrier substrate, particularly at higher frequencies.

One conventional technique for reducing the capacitive coupling between, for example, a carrier substrate pin pad slated for signals and an overlying conductor plane is to form a large hole in the conductor plane and position a via through the hole. The hole reduces the capacitive overlap area with the underlying pin pad. Such holes can be numerous for a given conductor plane if there are many signal pins and reduce the current carrying capability of the conductor plane.

Another conventional technique employs silicon level equalization techniques such as transmitter de-emphasis and receiver filtering in circuit design to compensate for the parasitics of the signal channels. This technique presents very challenging design complexities, particularly at higher frequencies or data rates of operation.

The present invention is directed to overcoming or reducing the effects of one or more of the foregoing disadvantages.

### SUMMARY OF THE INVENTION

In accordance with one aspect of the present invention, a method of manufacturing is provided that includes assembling a semiconductor chip carrier substrate with a first input/output site adapted to electrically connect to an external component and a second input/output site adapted to electrically connect to an input/output site of a semiconductor chip. An inductor is placed in the semiconductor chip carrier substrate. The inductor is electrically connected between the first input/output site or the second input/output site and a first conductor in the carrier substrate. The inductor has a preselected inductance to reduce an impedance discontinuity between the first input/output site or the second input/output site due to coupling to a second conductor in the semiconductor chip carrier substrate.

In accordance with another aspect of the present invention, a method of manufacturing is provided that includes forming a first conductor plane in a semiconductor chip carrier substrate. A first input/output site is formed on the semiconductor chip carrier substrate and adapted to electrically connect to an external component. A second input/output site is formed on the semiconductor chip carrier substrate and adapted to electrically connect to an input/output site of a semiconductor chip. A conductive pathway is formed between the first and second input/output sites. An inductor is formed in the semiconductor chip carrier substrate and the conductive pathway. The inductor has a preselected inductance to reduce an impedance discontinuity between the first input/output site or the second input/output site and a conductor in the carrier substrate due to coupling to the first conductor plane.

In accordance with another aspect of the present invention, an apparatus is provided that includes a semiconductor chip carrier substrate that has a first input/output site adapted to electrically connect to an external component and a second input/output site adapted to electrically connect to an input/output site of a semiconductor chip. An inductor is in the semiconductor chip carrier substrate and electrically connected between the first input/output site or the second input/output site and a first conductor in the carrier substrate. The inductor has a preselected inductance to reduce an impedance discontinuity between the first input/output site or the second input/output site and the first conductor due to coupling to a second conductor in the semiconductor chip carrier substrate.

### BRIEF DESCRIPTION OF THE DRAWINGS

The foregoing and other advantages of the invention will become apparent upon reading the following detailed description and upon reference to the drawings in which:

FIG. 1 is a sectional view of an exemplary embodiment of a semiconductor chip package seated in a socket of a printed circuit board;

FIG. 2 is a portion of FIG. 1 shown at greater magnification;

FIG. 3 is a schematic illustrating an exemplary electrical pathway of the semiconductor chip package and including an exemplary tuning inductor;

FIG. 4 is a partially exploded pictorial view of an exemplary embodiment of a tuning inductor coupled between two conductor structures of an exemplary semiconductor chip carrier substrate;

FIG. 5 is an overhead view of the inductor depicted in FIG. 4;

FIG. 6 is an overhead view of an alternate exemplary embodiment of a tuning inductor;

FIG. 7 is a partially exploded pictorial view of an exemplary conventional untuned electrical connection between a conductor pin and a conductor plane;

FIG. 8 is a sectional view depicting a portion of an exemplary carrier substrate and formation of a conductor plane and an exemplary tuning inductor thereon;

FIG. 9 is a sectional view like FIG. 8 but depicting formation of an input/output site in electrical communication with the inductor; and

FIG. 10 is a sectional view like FIG. 9 but depicting placement of a conductor pin on the input/output site.

### DETAILED DESCRIPTION OF SPECIFIC EMBODIMENTS

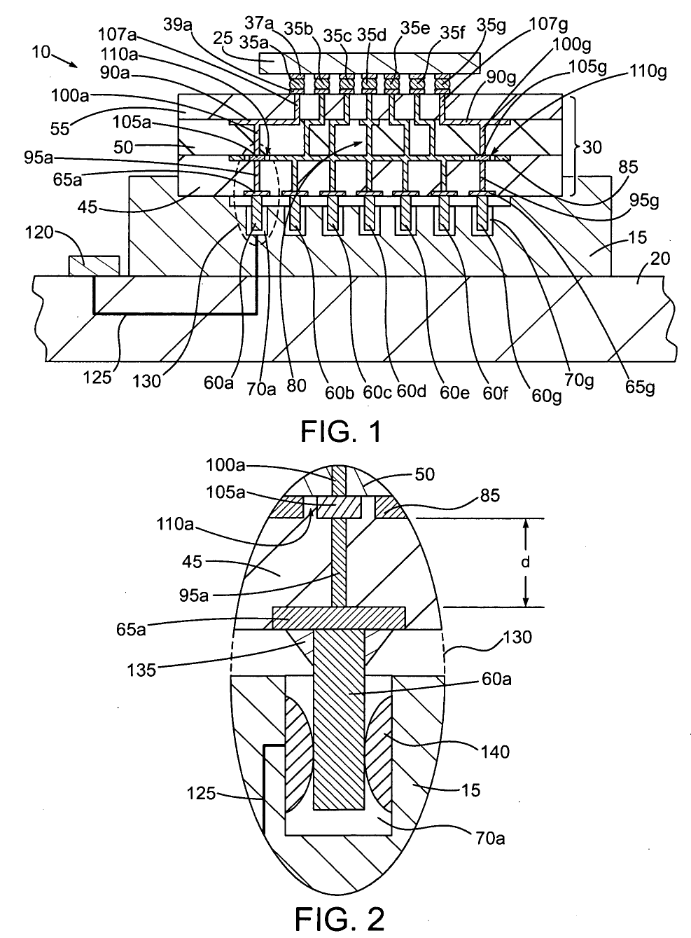

In the drawings described below, reference numerals are generally repeated where identical elements appear in more than one figure. Turning now to the drawings, and in particular to FIG. 1, therein is shown a sectional view of an exemplary embodiment of a semiconductor chip package 10 seated in a socket 15 of a printed circuit board 20. The semiconductor chip package 10 includes a semiconductor chip 25 mounted to a carrier or package substrate 30. The semiconductor chip 25 may be any of a myriad of different types of circuit devices used in electronics, such as, for example, microprocessors, graphics processors, combined microprocessor/graphics processors, application specific integrated circuits, memory devices or the like, and may be single or multi-core, or combined in a dice stack. The semiconductor chip 25 may be fabricated using silicon, germanium or other semiconductor materials. If desired, the semiconductor chip 25 may be fabricated as a semiconductor-on-insulator substrate or as bulk semiconductor.

The package substrate 30 provides electrical connectivity between the semiconductor chip 25 and the printed circuit board 20 by way of the socket 15. The printed circuit board 20 may be virtually any type of printed circuit board, such as a motherboard, a circuit card or the like. The socket 15 is depicted as a pin grid array socket. However, ball grid arrays, land grid arrays or other types of interconnects could be used.

In this illustrative embodiment, the semiconductor chip 25 is electrically connected to the carrier substrate 30 by way of a plurality of solder joints, a few of which are visible and labeled 35a, 35b, 35c, 35d, 35e, 35f and 35g. The following description of the solder joint 35a will be illustrative of the others 35b, 35c, 35d, 35e, 35f and 35g. The solder joint 35a is sandwiched between a conductor pad 37a of the semiconductor chip 25 and a conductor pad 39a of the carrier substrate 30. The conductor pad 37a provides an input/output site for electrical signals, power or ground. The pads 37a and 39a may be composed of various conductor materials, such as copper, gold, silver, aluminum, platinum, palladium, molybdenum, combinations of these or the like. The solder joint 35a may be composed of lead-based solders, lead-free solders, or combinations of the two. It should be understood that other types of interconnection schemes could be used, such as, conductive pillars, wire bonds or other interconnects as desired.

The carrier substrate 30 may be composed of ceramics or organic materials as desired. If organic, the substrate 30 may actually consist of multiple layers of metallization and dielectric materials. The substrate 30 may interconnect electrically with external devices, such as the socket 15, in a variety of ways, such as the depicted pin grid array, or optionally a land grid array, a ball grid array or other configuration. The number of individual layers for the substrate 30 is largely a matter of design discretion. In certain exemplary embodiments, the number of layers may vary from two to sixteen. If such a build-up design is selected, a standard core, thin core or coreless arrangement may be used. The dielectric materials may be, for example, epoxy resin with or without fiberglass fill. For simplicity of illustration, the illustrative embodiment of the package substrate 30 is shown with three layers 45, 50 and 55. To establish electrical contact with the socket 15, the substrate 30 is provided with a plurality of conductor pins, a few of which are visible and labeled 60a, 60b, 60c, 60d, 60e, 60f and 60g. The pins 60a, 60b, 60c, 60d, 60e, 60f and 60g are coupled to respective conductor pads, two of which are labeled 65a and 65g, respectively, and seat in respective socket holes of the socket 15, two of which are labeled 70a and 70g, respectively. In this example, the conductor pads 65a and 65g serve as input/output sites for electrical signals and the unlabeled conductor pads for the pins 60b, 60c, 60d, 60e and 60f serve as input/output sites for power or ground. In terms of composition, the conductor pads 65a and 65g may be like the conductor pads 37a and 39a described above. It should be understood that there may be large numbers of pins, solder joints and conductor pads.

The electrical pathways between the pins 60a, 60b, 60c, 60d, 60e, 60f and 60g and the solder joints 35a, 35b, 35c, 35d, 35e, 35f and 35g are provided by way of an interconnect system 80 in the package substrate 30. The interconnect system 80 may consist of several stacked layers of conductor planes and traces interconnected vertically by vias. The basic function of the interconnect system is to carry power and signals and provide a ground path between the semiconductor chip 25 and the pins 60a, 60b, 60c, 60d, 60e, 60f and 60g. It should be understood that the interconnect system 80 may include large numbers of conductor planes, traces and vias. However in this simplified example, the interconnect system 80 includes a conductor plane 85 positioned below a plurality of conductor traces, two of which are labeled 90a and 90g, respectively. The conductor plane 85 may connect the solder joints 35b, 35c, 35d, 35e and 35f to either power or ground by way of the pins 60b, 60c, 60d, 60e and 60f. If desired, the conductor plane 85 may be formed substantially like a conductive sheet that may extend across the entire expanse of the package substrate 30.

The conductor traces 90a and 90g in this example are slated to carry signals and thus should not be electrically connected to the conductor plane 85. The conductor trace 90a may be connected to the pin pad 65a by a via 95a, a via 100a and a tuning inductor 105a connected between the vias 95a and 100a. A via 107a connects the conductor trace 90a to the solder joint 35a. Another via 107g connects the conductor trace 90g to the solder joint 35g. To avoid shorting to the conductor plane 85, a cutout 110a is formed in the conductor plane 85 for the tuning inductor 105a. In a conventional design to be discussed in more detail below, the vias 95a and 100a would be merged and simply pass through the cutout 110a. However, in this illustrative embodiment, the tuning inductor 105a is positioned between the vias 100a and 95a to provide the capacity to tune out undesirable impedance discontinuity resulting from capacitive coupling between the conductor plane 85 and the underlying pin pad 65a. A corresponding tuning inductor 105g is provided in a cutout 110g in the conductor plane 85 between the vias 95g and 100g connecting the conductor trace 90g to the pin pad 65g.

Assume for the purposes of this illustration that an external component 120 is positioned on the printed circuit board 20 and electrically connected to the socket hole 70a, and thus the pin 60a, by way of a transmission line 125. The transmission line 125 is shown as a simplified electrical line, however, the transmission line 125 may be fabricated by a complex interconnect scheme on and/or in the printed circuit board 20 that is not unlike the interconnect scheme 80 associated with the package substrate 30, albeit, on a larger scale. The external component 120 may be virtually any type of integrated circuit that may be used in conjunction with the semiconductor chip package 10 and may function as a driver, a receiver or both. At this point, note the location of the dashed oval 130. The portion of FIG. 1 circumscribed by the dashed oval will be shown at magnification in FIG. 2.

Attention is now turned to FIG. 2. Note that the socket hole 70a, a portion of the socket 15, the conductor pin 60a, the pin pad 65a, the via 95a, a portion of the via 100a and a portion of the conductor plane 85 are visible. The conductor pin 60a may be coupled to the pin pad 65a by a solder bead 135 or by some other fastening technique. The socket hole 70a is provided with a contact structure 140 that engages the pin 60a. The contact structure 140 is connected to the aforementioned transmission line 125 that leads to the external component 120 shown in FIG. 1. The tuning inductor 105a is positioned in the cutout 110a and as discussed above, and electrically connected to the vias 95a and 100a. Some of the insulating layer 45 electrically insulates the tuning inductor 105a from the conductor plane 85 in the cutout 110a. The capacitive coupling Cₚₚ between the conductor plane 85 and the underlying pin pad 65a is a function of the area of overlap, A, of the pin pad 65a and the overlying conductor plane 85, the dielectric constant, ε, of the layer 45 and the spacing, d, between the conductor plane 85 and the underlying pin pad 65a according to:

$${C}_{pp} = \frac{ɛ A}{d} \qquad ( 1 )$$

However, the impedance discontinuity caused by this capacitive coupling Cₚₚ may be effectively tuned away by the incorporation of the inductor 105a.

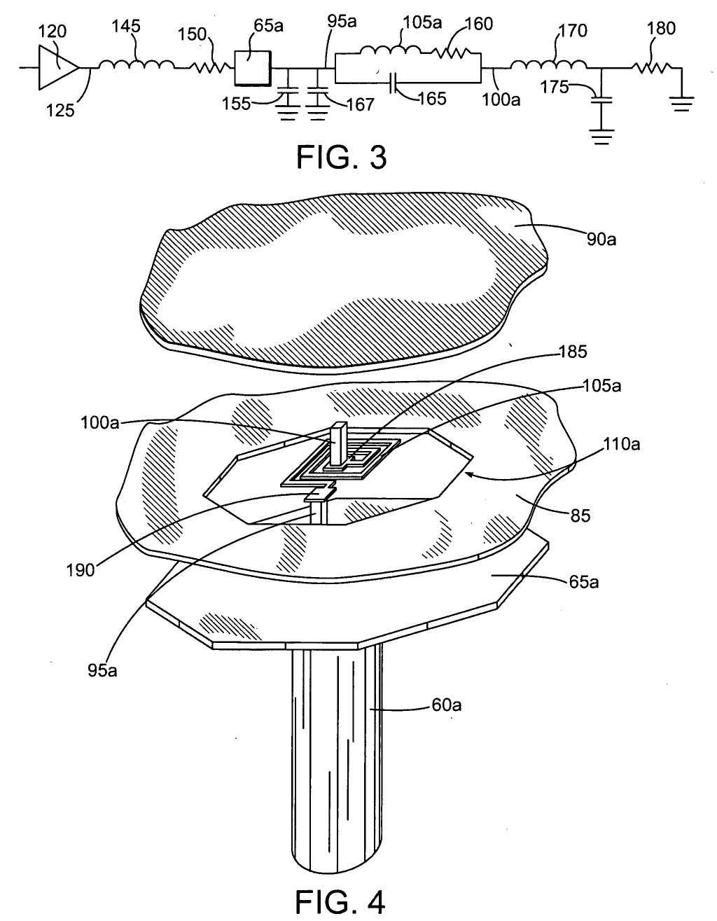

Attention is now turned again to FIG. 1 and now also to FIG. 3, which is a schematic diagram showing the circuit path between the external driver 120 and the solder joint 35a shown in FIG. 1. The inductor 145 represents the inductance associated with the transmission line 125 between the external component 120 and the socket hole 70a. The resistor 150 represents the impedance of the pin 60a shown in FIG. 1. The capacitor 155 represents the unwanted capacitance between the pin pad 65a and the overlying conductor plane 85 shown in FIG. 1. In order to tune out the effects of the capacitor 155, the tuning inductor 105a is connected between the via 95a and the via 100a. The tuning inductor 105a is not an ideal device, and thus has some impedance represented by the resistor 160, some capacitance due to inter-winding overlap represented by the capacitor 165, and some capacitance due to overlap with the pin pad 65a below and the conductor trace 90a above, collectively represented by the parallel capacitor 167. An inductor 170 connected to the via 95a represents the inductance of the conductor trace 90a, the via 100a and the via 107a depicted in FIG. 1. The capacitor 175 and the resistor 180 represent the solder joint 35a and circuitry in the semiconductor chip 25 connected thereto acting as a receiver. The tuning inductor 105a may be constructed to provide a selected inductance that effectively tunes out the impedance mismatch due to the capacitor 155. Of course the value of the inductance for the inductor 105a will be selected based upon the anticipated value of the capacitor 155. It should be understood that the capacitive coupling between the pin pad 65a and the overlapping portion of the overlying conductor plane 85 will be generally known since the overlap area will be known along with the distance, d, shown in FIG. 2 and the dielectric constant ε of the dielectric material layer 45. In essence, the capacitive coupling Cₚₚ becomes part of the tuned circuit that includes the tuning inductor 105a. A goal of the tuning is to reduce the impedance discontinuity encountered by signals delivered by the driver 120 and through the pin pad 65a for some frequency range of interest. The frequency range of interest will vary depending on a variety of parameters, such as the characteristics of the device driver 120, the carrier substrate 30 and the semiconductor chip 25. In an exemplary embodiment, the frequency range of interest includes frequencies above about 1 GHz.

A three dimensional depiction of one exemplary embodiment of the inductor 105a may be understood by referring now to FIG. 4, which is an exploded pictorial view showing the pin 60a, the pin pad 65a, a portion of the overlying conductor plane 85, the cutout 110a, the tuning inductor 105a and the overlying conductor trace 90a. For simplicity of illustration, the dielectric material that would be positioned between the pin pad 65a and the conductor plane 85, namely the insulating layer 45 shown in FIGS. 1 and 2, and the insulating material positioned between the conductor plane 85 and the overlying conductor trace 90a, namely the insulating layer 50 shown in FIGS. 1 and 2, are not shown. In this illustrative embodiment, the tuning inductor 105a consists of a multi-turn rectangular coil that has a pad 185 to which the via 100a is connected and another pad 190 to which the via 95a is connected. As mentioned elsewhere herein, the via 95a connects the tuning inductor 105a to the underlying pin pad 65a and the via 100a connects the tuning inductor 105a to the conductor trace 90a. The inductance value of the inductor 105a may be tailored by the number of turns, the spacing between individual turns, and for certain frequency ranges, the electrical conductivity or current carrying capability of the coils. Another parameter that may be varied to effect the tuning capability of the inductor 105a is the size of the cutout 110a. If the cutout 110a is increased in size, then the capacitive coupling between the conductor plane 85 and the underlying pin pad 65a will be reduced accordingly. It may also be possible to tailor the overlap area of the inductor 105a and the underlying pin pad 65a, which is represented schematically by the capacitor 167 in FIG. 3, to further refine the bandwidth characteristics of the tuning inductor 105a.

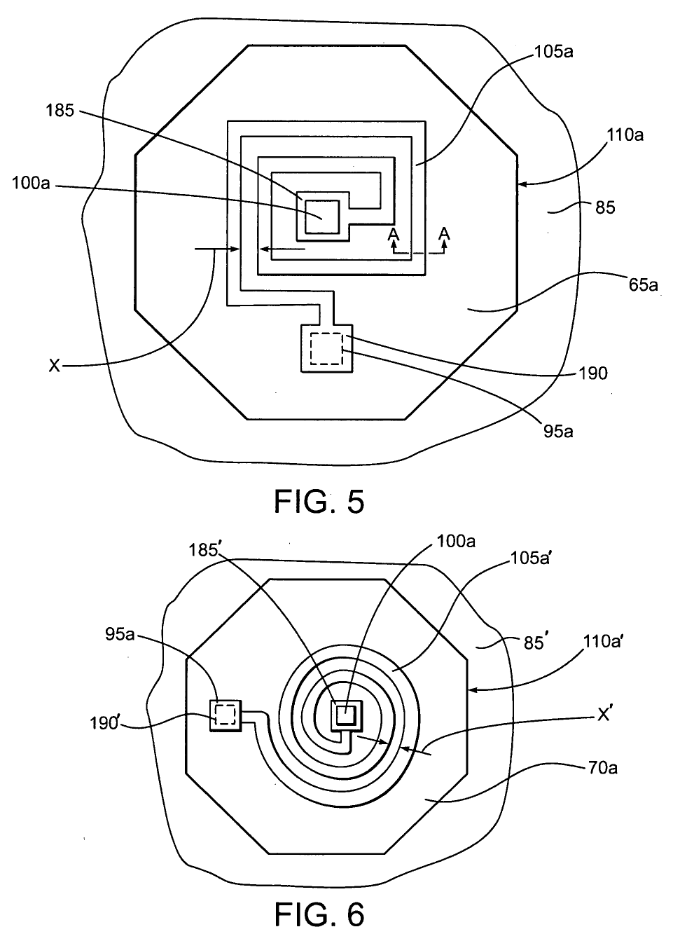

Additional detail of the exemplary inductor 105a may be understood by referring now to FIG. 5, which is an overhead view of the inductor 105a, the selected portion of the conductor plane 85, the cutout 110a and the revealed portion of the underlying pin pad 65a. In this illustrative embodiment, the tuning inductor 105a includes approximately three turns and a spacing X between coils. The number of turns, the spacing X, and the cross-sectional area (the area of section A-A) of the conductor trace that makes up the turns may be tailored to provide a selected level of inductance. In addition, the capacitive coupling between the tuning inductor 105a and the underlying pin pad 65a may be selected by tailoring the footprint of the inductor 105a and thus the area of overlap with the pin pad 65a. Indeed there may also be a capacitive coupling between the inductor 105a and the overlying conductor trace 90a (not visible in FIG. 5, but represented by the capacitor 167 in FIG. 3). Note that the cutout 110a is depicted as an octagonal structure. However, it should be understood that the cutout 110a may take on a great variety of geometric shapes.

In another alternate exemplary embodiment depicted in FIG. 6, an inductor 105a′ may have a generally circular or oval turn configuration as depicted. Here, a pad 185′ may provide an electrical connection to the via 100a and another pad 190′ may be connected to the via 95a which is beneath the pad 190′ and thus shown in phantom. Again, the number of turns of the tuning inductor coil 105a′ and the inter coil gap, X′, may be tailored to provide a selected level of inductance. The size of the cutout 110a′ in the conductor plane 85′ may also be varied as described elsewhere herein. It should be understood that a variety of inductor geometries other than rectangular and oval may be used, such as octagonal, hexagonal or others.

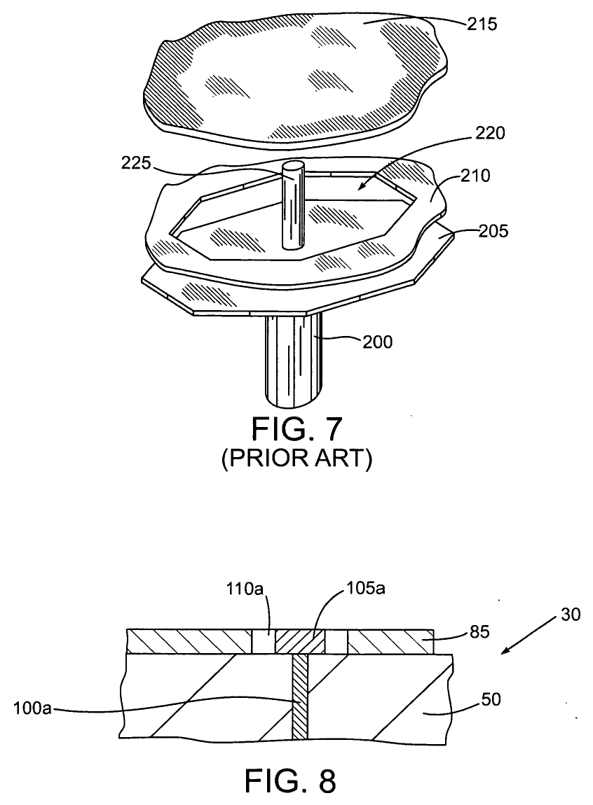

It may be useful at this juncture to contrast the tuned inductor design of the disclosed embodiments with a conventional pin pad to overlying conductor plane electrical pathway. In this regard, attention is now turned to FIG. 7, which is a partially exploded pictorial view not unlike FIG. 4, but of a conventional pin pad connector assembly. Again, now intervening insulating layers are not shown for simplicity of illustration. A conventional conductor pin 200 is connected to an overlying pin pad 205. An overlying conductor plane 210, a portion of which is visible in FIG. 7, is positioned above the pin pad 205 and a portion 215 of another conductor plane is positioned above the conductor plane 210. In this example, the conductor plane 210 may be, for example, a ground or power plane and the pin 200 may be slated for signal transmission. Thus, it is desired to establish an electrical connection between the pin pad 205 and the overlying conductor plane 215 which is slated for signal propagation without making connection to the conductor plane 210. A cutout 220 is formed in the conductor plane 210 over the pin pad 205 and a via 225 is formed on the pin pad 205 prior to the formation of the overlying conductor plane 215 and then the conductor plane 215 is formed in ohmic contact with the via 225. Here, however, the size of the cutout 220 is made relatively large in an attempt to reduce the capacitive coupling between the pin pad 205 and the overlying conductor plane 210. This, as noted in the Background section hereof, has an adverse impact on the current carrying capability of the conductor plane 210. Furthermore, there is no controlled tuning of the capacitance between the pin pad 205 and the overlying conductor plane 210.

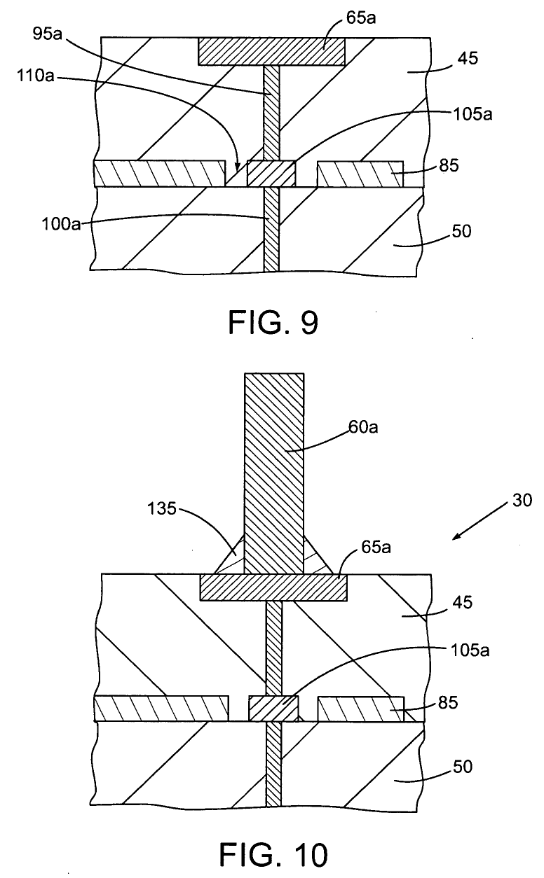

An exemplary method for fabricating any of the tuning inductors 105a, 105g and 105a′ disclosed herein may be understood by referring now to FIGS. 8 and 9 and initially to FIG. 8. It should be understood that FIG. 8 depicts the substrate 30 flipped over from the orientation shown in FIG. 1. At this stage of the processing depicted, the via 100a has been previously established in the substrate layer 50. The conductor plane 85 may be formed on the insulating layer 50 using a variety of materials and processes. For example, the conductor plane 85 may be composed of copper, gold, silver, aluminum, molybdenum, platinum, palladium, combinations of these or the like and applied by plating, chemical vapor deposition, physical vapor deposition or other techniques. The conductor plane 85 may be shaped lithographically if desired. The tuning inductor 105a may be fabricated in conjunction with or separately from the conductor plane 85. In the former variant, the tuning inductor 105a could be formed at the same time and of the same material(s) as the conductor plane 85. In the latter variant, the conductor plane 85 may be first formed, and the cutout 110a cut or otherwise made. The tuning inductor 105a could then be formed in the cutout, by conductor material deposition or plating and shaping. Appropriate masking and material removal steps may be performed in order to establish the cutout 110a and the tuning inductor 105a. If desired, a conductive paste that reduces the quality factor to some desired level may be applied. In still another variant, the tuning inductor 105a could be fabricated separately and thereafter fastened to the via 100a. Again it should be remembered that FIG. 8 is a sectional view and thus does not depict the true geometry of the tuning inductor 105a.

Next and as shown in FIG. 9, the insulating layer 45 is formed over the conductor plane 85, the cutout 110a and the tuning inductor 105a. Subsequently, an opening may be formed in the insulating layer 45 and the via 95a formed therein. The vias 95a and 100a may be composed of copper, gold, silver, aluminum, molybdenum, platinum, palladium, combinations of these or the like and applied by plating, chemical vapor deposition, physical vapor deposition or other techniques. Seed layers of tantalum, tantalum nitride or the like may be used if conductor material to insulator material adhesion or diffusion issues are present. The pin pad 65a may next be formed on the via 95a. The pin pad 65a may be formed from the same materials and using the same techniques as the vias 100a and 95a.

Finally, and as shown in FIG. 10, the conductor pin 60a may be joined to the pin pad 65a by the solder bead 135 or other fastening technique. The steps to fabricate the various structures, such as the insulating layers 50, 45, the inductor 105a, the conductor plane 85 and any others in the substrate 30 could conceivably be performed on en masse for multiple substrates in the form of say a strip and other grouping. Substrate singulation would follow.

The skilled artisan will appreciate that the same process would be used regardless of the particular shape of the inductor 105a or the type of interface connected to the pad 65a, such as a pin, a land grid or ball grid, a ball, etc. Furthermore, the number and locations of the tuning inductors used may be varied. For example, tuning inductors could be electrically connected between carrier substrate input/output (I/O) sites slated for chip connection and substrate conductors or between carrier substrate I/O sites slated for external component connection and substrate conductors. Different sizes and inductances can be selected for different tuning inductors. While the via pathways between a given I/O pad have been depicted as being generally vertically aligned, other geometries can be used with the disclosed tuning inductors.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
assembling a semiconductor chip carrier substrate with a first input/output site adapted to electrically connect to an external component and a second input/output site adapted to electrically connect to an input/output site of a semiconductor chip;
placing an inductor in the semiconductor chip carrier substrate; and
electrically connecting the inductor between the first input/output site or the second input/output site and a first conductor in the carrier substrate, the inductor having a preselected inductance to reduce an impedance discontinuity between the first input/output site or the second input/output site due to coupling to a second conductor in the semiconductor chip carrier substrate.

2. The method of claim 1, wherein the placing an inductor comprises forming an inductor coil in the semiconductor chip carrier substrate.

3. The method of claim 2, wherein the forming an inductor comprises forming a cutout in the second conductor and forming the inductor in the cutout.

4. The method of claim 1, wherein the forming an inductor comprises depositing a conductor material on a surface of the semiconductor chip carrier substrate and lithographically patterning the conductor material.

5. The method of claim 1, comprising coupling the semiconductor chip to the semiconductor chip carrier substrate and electrically connecting the second input/output site of the semiconductor chip carrier substrate the input/output site of the semiconductor chip.

6. The method of claim 1, comprising coupling a conductor to the first input/output site adapted to electrically connect to the external component, wherein the external component comprises a socket.

7. A method of manufacturing, comprising:
forming a first conductor plane in a semiconductor chip carrier substrate;
forming a first input/output site on the semiconductor chip carrier substrate adapted to electrically connect to an external component and a second input/output site on the semiconductor chip carrier substrate adapted to electrically connect to an input/output site of a semiconductor chip;
forming conductive pathway between the first and second input/output sites;
forming an inductor in the semiconductor chip carrier substrate and the conductive pathway, the inductor having a preselected inductance to reduce an impedance discontinuity between the first input/output site or the second input/output site and a conductor in the carrier substrate due to coupling to the first conductor plane.

8. The method of claim 7, wherein the forming an inductor comprises forming an inductor coil.

9. The method of claim 8, wherein the forming an inductor comprises forming a cutout in the first conductor plane and forming the inductor in the cutout.

10. The method of claim 7, wherein the forming an inductor comprises depositing a conductor material on an exposed surface of the semiconductor chip carrier substrate and lithographically patterning the conductor material and applying an insulating material over the inductor.

11. The method of claim 7, comprising coupling the semiconductor chip to the semiconductor chip carrier substrate and electrically connecting the second input/output site of the semiconductor chip carrier substrate to the input/output site of the semiconductor chip.

12. The method of claim 7, comprising coupling a conductor to the first input/output site adapted to electrically connect to the external component, wherein the external component comprises a socket.

13. An apparatus, comprising:
a semiconductor chip carrier substrate having a first input/output site adapted to electrically connect to an external component and a second input/output site adapted to electrically connect to an input/output site of a semiconductor chip; and
an inductor in the semiconductor chip carrier substrate and electrically connected between the first input/output site or the second input/output site and a first conductor in the carrier substrate, the inductor having a preselected inductance to reduce an impedance discontinuity between the first input/output site or the second input/output site and the first conductor due to coupling to a second conductor in the semiconductor chip carrier substrate.

14. The apparatus of claim 13, wherein the inductor comprises a coil.

15. The apparatus of claim 14, wherein the coil is positioned in a cutout in the second conductor.

16. The apparatus of claim 13, comprising a semiconductor chip coupled to the semiconductor chip carrier substrate and having an input/output site electrically connected to the second input/output site of the semiconductor chip carrier substrate.

17. The apparatus of claim 13, comprising a third conductor coupled to the first input/output site adapted to electrically connect to the external component.

18. The apparatus of claim 17, wherein third conductor comprises a pin and the external component comprises a socket.

19. The apparatus of claim 13, wherein the first and second input/output sites and the inductor conduct electrical signals to and from the external component.

20. The apparatus of claim 13, wherein the external component comprises a printed circuit board electrically connected to the first input/output site.
